(19) United States
(12) Patent Application Publication
(10) Pub. No.: US 2026/0123527 A1
(43) Pub. Date: Apr. 30, 2026

(54) PACKAGE WITH REDISTRIBUTION STRUCTURE AND METHOD FOR FORMING THE SAME

(71) Applicant: Taiwan Semiconductor Manufacturing Company, Ltd., Hsinchu (TW)

(72) Inventors: Kuan-Chung Pan, Hsinchu (TW); Jian-Yang He, Tainan City (TW); Tzung-Hui Lee, New Taipei City (TW); Hung-Jui Kuo, Hsinchu City (TW)

(73) Assignee: Taiwan Semiconductor Manufacturing Company, Ltd., Hsinchu (TW)

(21) Appl. No.: 18/929,517

(22) Filed: Oct. 28, 2024

(51) Int. Cl. H01L 23/00; H01L 23/31; H01L 25/065

(52) U.S. Cl. CPC H10W 90/00; H10W 70/09; H10W 70/60; H10W 74/141; H10W 90/10

(57) ABSTRACT

A package and a manufacturing method for the package are provided. The package includes a semiconductor die, an insulating encapsulant and a redistribution structure. The redistribution structure comprises a dielectric layer and a stacked via structure embedded in the dielectric layer. The stacked via structure comprises a first via plug, a first diffusion layer including first dopants, a second via plug, and a second diffusion layer including second dopants. The first via plug includes the first dopants dispersed within a first metal material of the first via plug, and the second via plug includes the second dopants dispersed within a second metal material of the second via plug.

### BACKGROUND

During the packaging processes of the semiconductor dies, redistribution structures including metallic routing patterns, pads and vias are formed for routing and interconnecting the dies and/or semiconductor devices in the packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 are schematic cross-sectional views of various stages in a manufacturing method for forming a semiconductor package structure according to some exemplary embodiments of the present disclosure.

FIG. 7A to FIG. 7F are schematic enlarged cross-sectional views of various stages in a manufacturing method for forming stacked vias in the redistribution structure according to some exemplary embodiments of the present disclosure.

FIG. 8 is a schematic cross-sectional view of a portion of a semiconductor package structure with stacked vias according to an exemplary embodiment of the present disclosure.

FIG. 9 schematically illustrates the stacked vias and a portion of routing patterns in the redistribution structure in accordance with embodiments of the present disclosure.

FIG. 10 is a schematic cross-sectional view illustrating a package structure having stacked vias with the according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

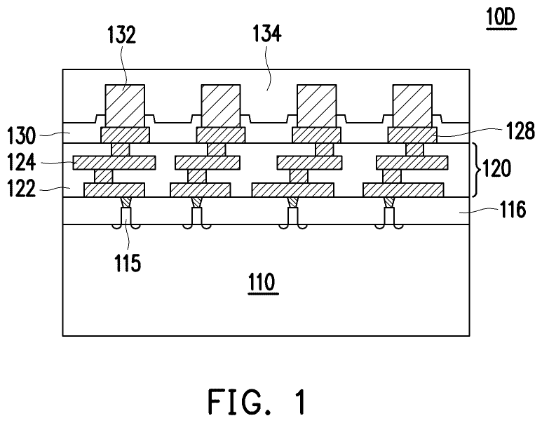

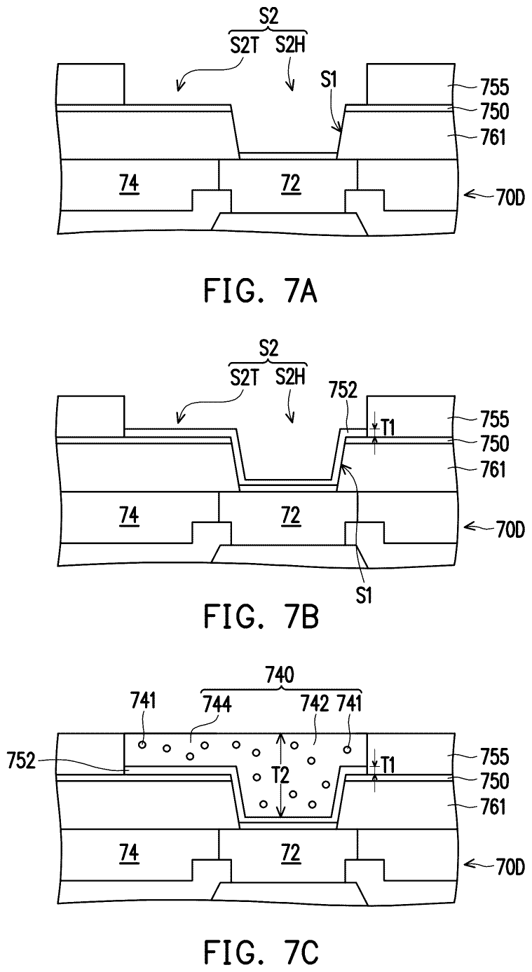

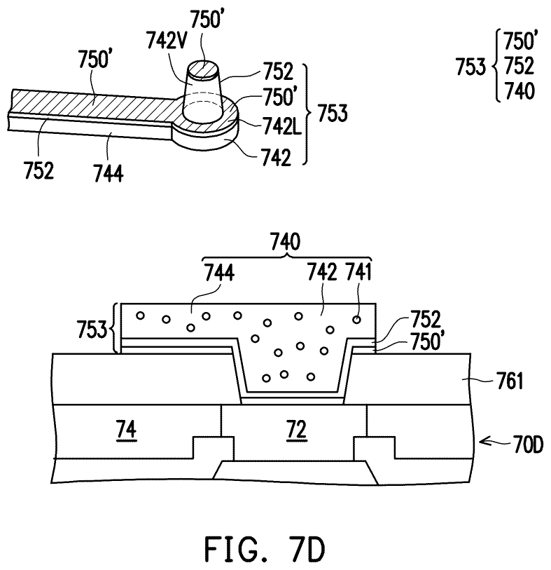

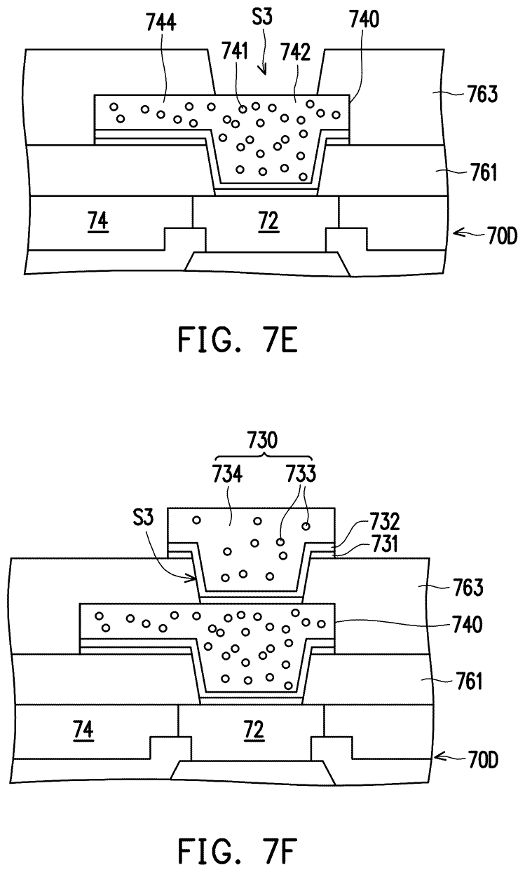

FIG. 1 to FIG. 6 are schematic cross-sectional views of various stages in a manufacturing method for forming a semiconductor package structure having a redistribution structure according to some exemplary embodiments of the present disclosure. FIG. 7A to FIG. 7F are schematic enlarged cross-sectional views of various stages in a manufacturing method for forming stacked vias in the redistribution structure according to some exemplary embodiments of the present disclosure.

Referring to FIG. 1, a semiconductor die 10D is provided. The semiconductor die 10D may be an integrated circuit die formed from a semiconductor wafer. In some embodiments, the semiconductor die 10D includes a semiconductor substrate 110 and semiconductor devices 115 formed from, on or in the semiconductor substrate 110. For example, the semiconductor substrate 110 may include a bulk silicon substrate, doped or undoped, or an active layer of a semiconductor-on-insulator (SOI) substrate. In some embodiments, the semiconductor substrate 110 may include other semiconductor materials, such as germanium, a compound semiconductor material (such as silicon carbide, gallium arsenic, gallium phosphide, indium phosphide, indium arsenide, and indium antimonide), an alloy semiconductor (such as SiGe, GaAsP, AlInAs, AlGaAs, GaInAs, GaInP, and GaInAsP). In some embodiments, the semiconductor substrate 110 may be or includes multi-layered or gradient substrates. For example, the semiconductor devices 115 are formed within a device layer 116 over the semiconductor substrate 110. In some embodiments, the device layer 116 is formed with the semiconductor devices 115 including active devices (e.g., transistors, diodes, etc.), and optionally passive devices (e.g., capacitors, resistors, inductors, etc.).

In addition, referring to FIG. 1, the semiconductor die 10D further includes an interconnection structure 120 on the device layer 116, conductive pads 128 connected to the interconnection structure 120, a passivation layer 130 covering the conductive pads 128 and the interconnection structure 120, conductive posts 132 disposed on the conductive pads 128, and a protection layer 134 covering the conductive posts 132 and the passivation layer 130. In some embodiments, the interconnection structure 120 includes metallization patterns 124 embedded within a dielectric material 122. For example, the metallization patterns 124 that include metal lines and vias are embedded in the dielectric material 122 formed as one or more low-k dielectric layers. The interconnection structure 120 electrically interconnects the semiconductor devices 115 in the device layer 116 to form integrated circuits and electrically connects the semiconductor devices 115 in the device layer 116 with the conductive pads 128 and the conductive posts 132. In some embodiments, the passivation layer 130 is formed over the interconnection structure 120 over the semiconductor substrate 110 and has contact openings that expose the conductive pads 128. For example, the conductive pads 128 may be or include aluminum pads, copper pads, or other suitable metal or metallic pads, and the passivation layer 130 may be or include a silicon oxide layer, a silicon nitride layer, a silicon oxy-nitride layer, or a dielectric layer formed by other suitable dielectric materials. In some embodiments, the conductive posts 132 are formed on the conductive pads 128 through plating. In some embodiments, the conductive posts 132 include metallic posts such as copper posts or copper alloy posts. The conductive posts 132 may function as die connectors. For example, the protection layer 134 formed over the passivation layer 130 may include multiple layers and include at least a polyimide (PI) layer, a polybenzoxazole (PBO) layer, or a dielectric layer formed by other suitable polymers. The protection layer 134 is formed over the passivation layer 130 fully covering the conductive posts 132.

In some embodiments, the semiconductor die 10D may be or include a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an optoelectronic die, or a sensor die. In some embodiments, the semiconductor die 10D may be a stacked structure including multiple semiconductor dies, such as a hybrid memory cube (HMC) die, or a high bandwidth memory (HBM) die.

In some embodiments, the semiconductor die 10D is a known good die (KGD) that passes the chip testing, and only the KGDs undergo subsequent processing. In the following figures, for simplification purposes, the semiconductor devices formed in the device layer 116 as well as the detailed construction of the interconnection structure 120 will be omitted.

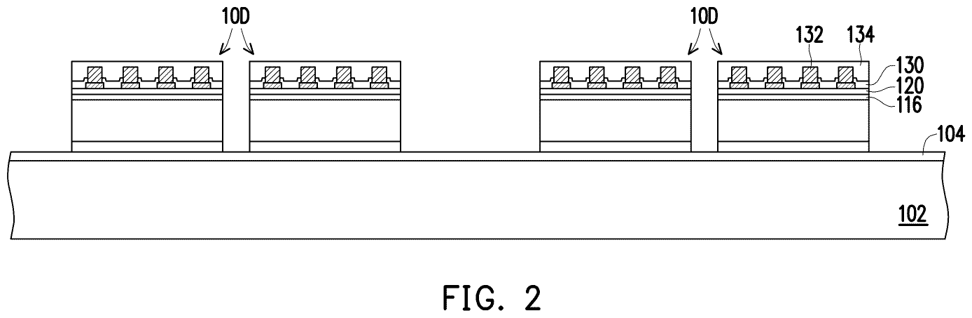

In some embodiments, referring to FIG. 2, a carrier 102 with a debonding layer 104 coated thereon is provided. In some embodiments, the carrier 102 includes any suitable carrier for the manufacturing method of the integrated fan-out (InFO) package structure. In some embodiments, the carrier 102 is a glass carrier or a temporary carrier. In some embodiments, the debonding layer 104 is formed from any material suitable for bonding and debonding the carrier 102 from the above component(s) or any die(s) disposed thereon. In some embodiments, the debonding layer 104 includes a light-to-heat-conversion (LTHC) release coating film, possible for room temperature debonding from the carrier 102 by applying laser irradiation. In some embodiments, the debonding layer 104 includes an ultra-violet (UV) glue, which loses its adhesive property when exposed to UV lights. In certain embodiments, the debonding layer 104 may be dispensed as a liquid and cured, or may be a laminate film laminated onto the carrier 102.

Referring to FIG. 2, after providing the carrier 102 with the debonding layer 104, several semiconductor dies 10D are provided and placed on the carrier 102. In some embodiments, a plurality of semiconductor dies 10D are picked and placed on the carrier 102. In some embodiments, the semiconductor dies 10D are arranged side-by-side and are placed with their backsides facing the debonding layer 104, so that the backsides of the semiconductor dies 10D are attached to the debonding layer 104. In the embodiments described herein, the manufacturing processes are directed to die-first and face-up wafer level packaging processes.

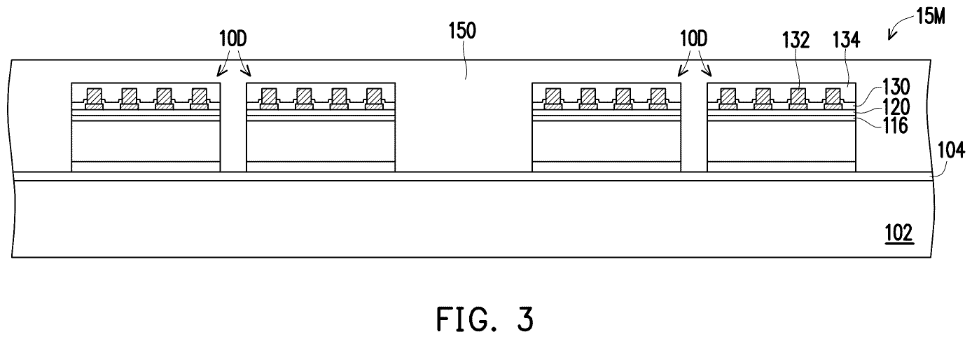

Referring to FIG. 3, an insulation encapsulant 150 is formed over the top surface of the carrier 102, fully covering the semiconductor dies 10D and filling between the semiconductor dies 10D, to encapsulate the semiconductor dies 10D to form a molded structure 15M. In some embodiments, the insulation encapsulant 150 includes a resin material such as epoxy resins, phenolic resins, silicon-containing resins or combinations thereof, and fillers including silica fillers or metal oxide fillers. In some embodiments, the method of forming the insulation encapsulant 150 includes forming an insulating resin material (not shown) on the debonding layer 104 over the carrier 102 through a molding process (e.g., transfer molding, compression molding or over molding) so as to fully cover and encapsulate the semiconductor dies 10D. In some embodiments, the insulation encapsulant 150 fully covers the top surfaces and sidewalls of the semiconductor dies 10D. Referring to FIG. 1 and FIG. 3, in some embodiments, the conductive posts 132 of the semiconductor dies 10D are covered by the protection layer 134, so that the conductive posts 132 of the semiconductor dies 10D are not revealed and are well protected by the protection layer 134.

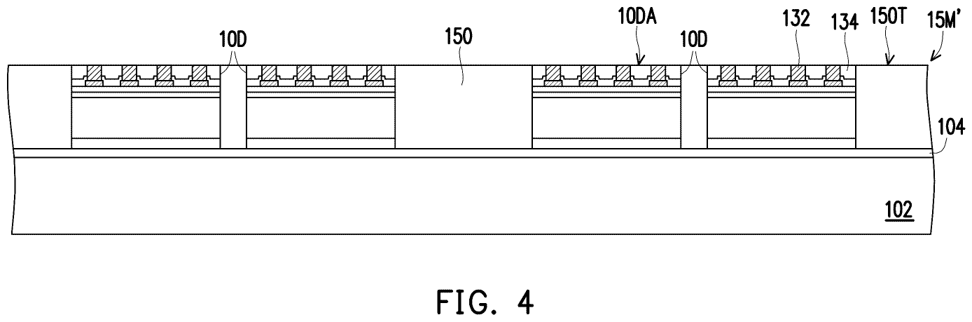

Referring to FIG. 4, in some embodiments, a planarization process is performed to partially remove the insulation encapsulant 150 of the molded structure 15M to become the reconstructed wafer 15M′. In some embodiments, during the planarization process, the insulation encapsulant 150 is partially removed along with partially removing the protection layer 134 until the tops of the conductive posts 132 are exposed. In some embodiments, the planarization process includes performing a mechanical grinding process and/or a chemical mechanical polishing (CMP) process. In some embodiments, after the planarization process, the conductive posts 132 of the semiconductor dies 10D are exposed from the polished protection layer 134 and from the polished insulation encapsulant 150. After performing the planarization process, the active surfaces 10DA of the semiconductor dies 10D are coplanar with and flush with the top surface 150T of the polished insulation encapsulant 150. That is, the conductive posts 132 are exposed from the active surface 10DA of the semiconductor dies 10D.

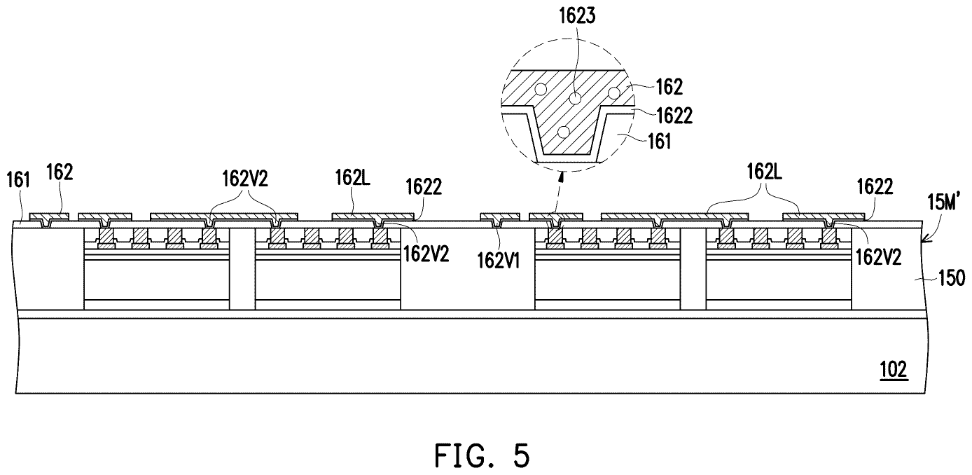

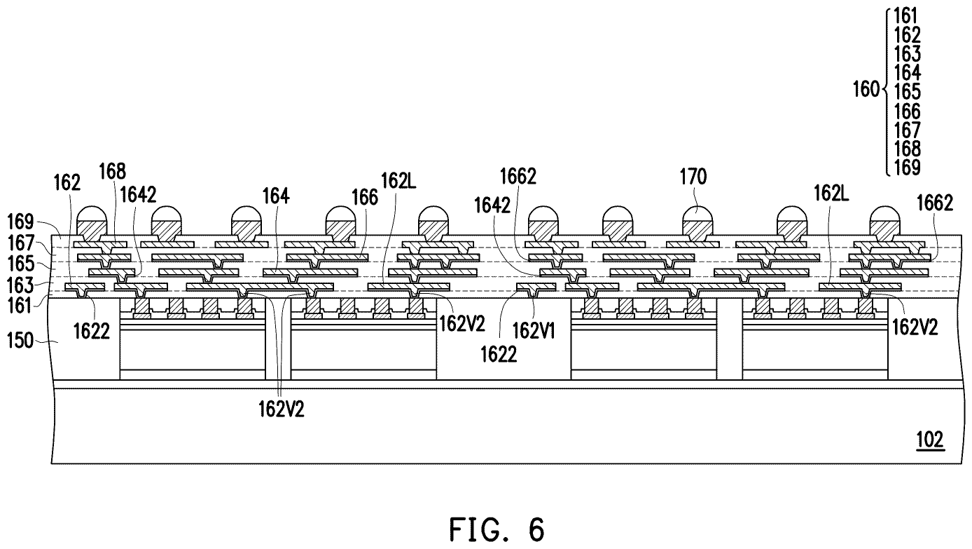

Referring to FIG. 5 and FIG. 6, a redistribution structure 160 is formed over the top surface of the reconstructed wafer 15M′, and the bump connectors 170 are formed on the redistribution structure 160. In some embodiments, the bump connectors 170 are or include ball grid array (BGA) connectors, solder balls, metal pillars, controlled collapse chip connection (C4) bumps, micro bumps, electroless nickel-electroless palladium-immersion gold technique (ENEPIG) formed bumps, or the like.

In some embodiments, the redistribution structure 160 is disposed on the semiconductor dies 10D and spreading over the polished insulation encapsulant 150 that laterally wrap around the semiconductor dies 10D over the carrier 102. In some embodiments, the redistribution structure 160 includes dielectric layers 161, 163, 165, 167, 169 and conductive layers 162, 164, 166, 168 arranged in alternation, and the conductive layers 162, 164, 166, 168 are sandwiched between the dielectric layers 161, 163, 165, 167, 169. The conductive layers 162, 164, 166, 168 may be referred to as redistribution layers and include metallization patterns. Herein, the redistribution structure 160 is shown as an example having four layers of metallization patterns sandwiched between five dielectric layers. However, it is understood that more or fewer dielectric layers and metallization patterns may be formed in the redistribution structure 160. If fewer dielectric layers and metallization patterns are to be formed, steps and processes discussed below may be omitted. If more dielectric layers and metallization patterns are to be formed, steps and processes discussed below may be repeated.

In some embodiments, referring to FIG. 5, the formation of the redistribution structure 160 starts with depositing the dielectric layer 161 over the semiconductor structure 101. In some embodiments, the material of the dielectric layer 161 includes polyimide (PI), epoxy resin, acrylic resin, phenol resin, benzocyclobutene (BCB), polybenzooxazole (PBO), or any other suitable polymer-based dielectric material. The dielectric layer 161, for example, may be formed by suitable fabrication techniques such as spin-on coating, chemical vapor deposition (CVD), plasma-enhanced chemical vapor deposition (PECVD), or the combination thereof. In some embodiments, the material of the dielectric layer 161 includes a photo-sensitive polymeric material that is directly patternable using a lithography mask. After forming the dielectric layer 161, the conductive layer 162 is then formed on the dielectric layer 161. In some embodiments, the conductive layer 162 is formed with metallization patterns including routing line 162L and vias 162V1 and 162V2. Referring to FIG. 5, the routing line 162L (e.g., conductive lines or traces) is located on and extends along the top surface of the dielectric layer 161, while the vias 162V1 and 162V2 extend through the dielectric layer 161 to physically contact and electrically couple to the respective conductive posts 132 (die connectors) of the semiconductor dies 10D. In some embodiments, a seed layer (not shown) and a diffusion layer 1622 is formed right below the conductive layer 162 and covering the bottom surface of the conductive layer 162, as seen in the partially enlarged view at the upper part of FIG. 5. Also, the conductive layer 162 is formed with dopants 1623 dispersed therein.

An example of the formation of the redistribution structure will be described in further details through the formation method(s) illustrated from FIG. 7A to FIG. 7F.

FIG. 7A to FIG. 7F illustrates cross-sectional views of a portion of the redistribution structure 760 in accordance with some embodiments. In the illustrated embodiments, the redistribution structure 760 formed on the semiconductor die 70D may be implemented as a part of the redistribution structure 160 formed on the semiconductor die 10D within the reconstructed wafer 15M′ (see FIG. 5 and FIG. 6). The semiconductor die 70D is similar to the semiconductor die 10D illustrated above with reference to FIG. 1, with similar features being labeled with similar numerical references, and the descriptions of the similar features are not repeated herein. For example, the semiconductor die 70D includes conductive posts 72 exposed from the protection layer 74.

Referring to FIG. 7A, in some embodiments, a dielectric layer 761 is formed on the semiconductor die 70D. In some embodiments, the material of the dielectric layer 761 includes a photo-sensitive polymeric material that is directly patternable using a lithography mask. In one embodiment, the dielectric layer 761 is formed by spin coating, deposition, or lamination. In some embodiments, the dielectric layer 761 is formed by spin coating. The dielectric layer 761 is then patterned to form openings S1 (only one is shown) at least exposing the conductive posts 72 of the semiconductor die 70D. When the dielectric layer 761 is made of a photo-sensitive material such as PBO or PI, the patterning may include performing any acceptable process, such as exposing the dielectric layer 761 to light and then developing to remove the unexposed parts to form openings S1. In some embodiments, a baking process may optionally be performed before or after exposure. Alternatively, the dielectric layer 761 may be patterned by etching using, for example, an anisotropic etch along with photoresist patterns. In some embodiments, an annealing process is performed to the dielectric layer 761, and the annealing process is performed under a temperature higher than 200 degrees Celsius. In one embodiment, the annealing process is performed under the temperature at about 230 degrees Celsius for a period of about 2-6 hours.

Referring to FIG. 7A, in some embodiments, a seed layer 750 is formed over the dielectric layer 761 with the opening(s) S1. In some embodiments, the seed layer 750 is formed over the dielectric layer 761 and in the openings covering the bottom surface of the opening S1. In some embodiments, the seed layer 750 is a single metal layer or a composite layer comprising a plurality of sub-layers formed of different metal or metallic materials. In some embodiments, the metallic material of the seed layer 750 includes silver, copper, antimony, titanium, alloys thereof or combinations thereof. In one embodiment, the seed layer 750 comprises a titanium layer as a diffusion barrier and a copper layer over the titanium layer. The seed layer 750 may be formed using, for example, physical vapor deposition (PVD) or sputtering. In embodiments, the thickness of the seed layer or the remained seed pattern 750′ is pretty thin, and it is acceptable that the seed layer does not remain as a continuous layer. Referring to FIG. 7A, the seed layer 750 covers the top surface of the dielectric layer 761 and the bottom surface of the opening(s) S1 without covering the sidewalls of the opening(s) S1 due to the profile of the opening(s) S1. In some other embodiments, the seed layer 750 not only covers the dielectric layer 761 but also conformally covers the opening(s) S1.

Referring to FIG. 7A and FIG. 7B, in some embodiments, a photoresist pattern 755 with openings S2 (only one is shown) is then formed on the seed layer 750. For example, the photoresist pattern 755 is formed by spin coating, cured and then exposed to light for patterning. In some embodiments, in FIG. 7A, the photoresist pattern 755 is disposed directly on the seed layer 750, covering the seed layer 750 but exposing the openings S1 and partially exposing the seed layer 750 around the opening(s) S1. In some embodiments, the opening S2 includes a trench opening S2T and a hole opening S2H joined with the trench opening S2T. In some embodiments, the hole opening S2H joined with the underlying opening S1 form a via plug opening. The patterns of the photoresist pattern 755 and the dielectric layer 761 correspond to the patterns of the to-be-formed metallization patterns. For example, the locations and profiles of the via plug opening(s) correspond to the to-be-formed via plug.

Referring to FIG. 7B, a diffusion layer 752 is formed in the openings S2 and S1 and on the exposed seed layer 750. In some embodiments, the diffusion layer 752 is formed on the seed layer 750 exposed by the opening(s) S2 and conformally covers the opening(s) S1 (directly on the sidewalls of the opening(s) S1 and on the seed layer 750 on the bottom surface of the opening(s) S1). In some embodiments, the formed diffusion layer 752 may be conformal to the profile of the opening(s) S1 and evenly cover the bottom surface(s) of the opening(s) S2. For example, the diffusion layer 752 may be formed by plating, using the exposed portions of the seed layer 750 as the seed, so that the diffusion layer 752 is formed on the seed layer 750 exposed by the opening(s) S2, extending along the sidewalls of the opening(s) S1 and extending over and covering the seed layer 750 on the bottom surface(s) of the opening(s) S1, but the diffusion layer 752 does not extend over the sidewalls of the opening(s) S2 or over the top surface of the photoresist pattern 755. In some embodiments, the diffusion layer 752 is formed by plating, such as electroplating or electrochemical plating, or the like.

In some embodiments, the diffusion layer 752 includes or is made of a metal layer, and the material of the metal layer includes silver (Ag), manganese (Mn), zinc (Zn), alloys thereof or combinations thereof. The diffusion layer 752 includes metal atoms that can easily diffuse into the later formed metal or metallic feature (i.e., conductive layer). In some embodiments, the diffusion layer 752 may function as a source for supplying dopants (i.e. a dopant supplying layer) for doping the later formed conductive layer. That is, the diffusion layer 752 includes dopants. The thickness of the diffusion layer 752 is tunable depending on the size or thickness of the later formed feature or layer, and is tuned to be thick enough to supply sufficient dopants or metal atoms into the above feature or layer. In some embodiments, the diffusion layer 752 is formed with a substantially uniform thickness. In some embodiments, the thickness T1 of the diffusion layer 752 may range from about 0.01 microns to about 1.0 micron, or from about 0.1 microns to about 0.5 microns. In other embodiments, it is possible that the diffusion layer 752 located on the seed layer 752 on the dielectric layer 761 is thicker than the diffusion layer 752 located on the sidewalls of the opening S1, and is no thinner (about the same) than the diffusion layer 752 located on the bottom surface of the opening S1.

Referring to FIG. 7C, a conductive layer 740 is formed on the diffusion layer 752, inside the patterns (e.g., inside the openings S2) of the photoresist pattern 755, and fills up the openings S1 and S2. In some embodiments, the conductive layer 740 is formed by forming a metal material (not shown) over and covering the photoresist pattern 755, filling into the openings S1 and S2, covering the diffusion layer 752 on the seed layer 750 through plating, and later the extra metal material is removed. For example, the extra metal material located above the photoresist pattern 755 is removed by etching, and the conductive layer 740 is levelled and flush with the top surface of the photoresist pattern 755.

Referring to FIG. 7C, in some embodiments, the conductive layer 740 includes metallization patterns formed as routing traces (or routing lines) 744 formed in the trench opening S2T and via plugs 742 formed inside the via plug opening (the hole opening S2H joined with the opening S1). In some embodiments, the metal material for the conductive layer 740 is formed by plating, such as electroplating or electrochemical plating, or the like. The metal material may comprise aluminum, titanium, copper, nickel, tungsten, cobalt and/or alloys thereof, for example. In some embodiments, the conductive layer 740 fills up the openings S1 and S2, and the thickness of the conductive layer 740 may be in a range from about 0.5 microns to about 10 microns, depending on the thicknesses of the photoresist pattern 755 and the dielectric layer 761. In some embodiments, the bulk thickness T2 of the via plug 742 of the conductive layer 740 ranges from about 1.5 microns to about 6 microns. Referring to FIG. 7C, in some embodiments, relative to the bulk thickness T2 of the via plug 742 of the conductive layer 740, the thickness T1 of the diffusion layer 752 may range from about 1% of T2 to about 20% of T2, as long as the diffusion layer 752 can provides sufficient dopants or doping atoms. In one embodiment, the thickness T1 is larger than 1% of the thickness T2 and less than or equivalent to 15% of the thickness T2.

Referring to FIG. 7C, during the formation of the conductive layer 740, dopants 741 diffuse from the diffusion layer 752 into the conductive layer 740. That is, the conductive layer 740 is formed with dopants 741 embedded therein. In some embodiments, the dopants 741 are or include metal atoms that are initially included and contained within the metal material of the diffusion layer 752, and the dopants 741 may be present in the conductive layer 740 as solitary metal atoms, or in the form as tiny grains or particles. For example, the metal material of the conductive layer 740 is like a solid solution with the metal atoms (dopants 741) dispersed therein. It is understood that the dopants 741 (shown as small circles in the figures) present in the atomic scales may be unseen by naked eyes but are detectable by microscopic inspections. In some embodiments, the conductive layer 740 is formed with dopants 741 contained therein, and an average content of the dopants 741 is about 5 at % (atomic percent) to about 11 at %, relative to total numbers of atoms of the whole conductive layer 740.

For example, for the diffusion layer 752, it is considered the content of the dopants 741 (e.g. metal atoms) is much higher that a content of the dopants 741 within the conductive layer 740. It is because the diffusion layer 752 may be formed with a bulk metal material consisting of the dopants or metal atoms, and some metal atoms may diffuse out of the diffusion layer 752 and move from the contact surface into the conductive layer 740 through thermal driven atom diffusion. In some embodiments, the concentration of the dopants 741 in the conductive layer 740 may be gradually decreased from the interface (contact surface) between the conductive layer 740 and the diffusion layer 752. That is, more dopants 741 are located in the region of the conductive layer 740 near the contact surface (interface) of the conductive layer 740 and the diffusion layer 752, while less dopants 741 are located in the region of the conductive layer 740 far away from the contact surface (interface) of the conductive layer 740 and the diffusion layer 752.

In some embodiments, the material of the diffusion layer 752 includes silver (Ag), manganese (Mn) or zinc (Zn), and the dopants 741 include atoms of Ag, atoms of Mn or atoms of Zn. In some embodiments, the material of the diffusion layer 752 includes silver or the diffusion layer 752 includes a silver layer, and the dopants 741 include atoms of Ag, either solo atoms or clusters of atoms. With the presence of the diffusion layer 752, using the copper electrochemical plating (ECP) process as an example for forming the conductive layer 740, copper is co-plated along with the metal atoms such as Ag atoms diffused out of the diffusion layer 740, so that the plated copper is formed with smaller crystal grain sizes and more or a larger portion of the copper is formed with a preferred crystal orientation such as Cu (111), compared with copper formed from the same plating process without the existence of the diffusion layer 752.

Referring to FIG. 7D, the photoresist pattern 755 is removed by a suitable etching process using plasma (such as using an oxygen plasma) and/or an acceptable ashing or stripping process. When the photoresist pattern 755 is removed, the seed pattern 750′ is formed by removing the portions of the seed layer 750 underlying the photoresist pattern 755 through the same process, or by using an additional etching process, such as wet etching or dry etching. Herein, the photoresist pattern 755 and the portions of the seed layer 750 on which the conductive material is not formed are removed.

As seen in the schematic three-dimensional view at the upper part of FIG. 7D, a portion of the stack 753 of the conductive layer 740, the underlying diffusion layer 752 and the seed pattern 750′ is shown in an upside-down view, the diffusion layer 752 fully covers the whole bottom surface of the conductive layer 740 (including bottom surface of the routing trace 744 and bottom surface of the via plug 742), while the seed pattern 750′ covers the bottom surface of the protruded portion 742V of the via plug 742, the bottom surface of the lip portion 742L of the via plug 742 and the bottom surface of the routing trace 744.

In some embodiments, after removing the photoresist pattern 755, the stack 753 (or combination) of the conductive layer 740, the underlying diffusion layer 752 and the seed pattern 750′ remains as metallization patterns disposed on the dielectric layer 761 and contacts (in physical and electrical contact with) the conductive posts 72 of the semiconductor die 70D. In embodiments, the thickness of the diffusion layer 752 is thick enough so that the diffusion layer 752 remains on the bottom surface of the conductive layer 740, even some metal materials of the diffusion layer 752 is consumed or diffused out of the diffusion layer 752.

Referring to FIG. 7E, in some embodiments, a dielectric layer 763 is formed on the dielectric layer 761 covering the conductive layer 740 and formed with openings S3 (only one is shown) exposing portions of the conductive layer 740. The material and the formation method of the dielectric layer 763 may be the same as or similar to those of the dielectric layer 761, and the detailed descriptions are skipped herein. In some embodiments, during the formation of the dielectric layer 763, an annealing process performed at the temperature of about 230 degrees Celsius for about 2-6 hours is performed to set the dielectric layer 763. During the annealing process, the conductive layer 740 and the underlying diffusion layer 752, at the same time, also undergo the annealing, and more dopants 741 diffuse out of the diffusion layer 752 into the conductive layer 740 so as to further increase the dopant content in the conductive layer 740 (especially the via plug 742). In some embodiments, after the annealing process, the content of the dopants 741 is about 7 at % to about 12 at %, relative to total numbers of atoms of the whole conductive layer 740.

Through such annealing process, more of the conductive layer 740 is formed in the preferred crystal orientation, leading to further reduced crystal grain sizes and increased grain boundaries formed in the metal material of the conductive layer 740. When the metal material of the conductive layer 740 is formed with smaller crystal grain sizes or increased grain boundaries, the resistance to dislocation is increased, and the conductive layer 740 offers a higher mechanical strength (including higher hardness and higher toughness) and a higher Young's modulus. With the presence of the diffusion layer 752, during the annealing process, using the copper as an example for forming the conductive layer 740, more and more copper may change into (turn into) the preferred crystal orientation such as Cu (111), and the crystal grain size(s) of the copper may be further reduced. In some embodiments, the diffusion layer 752 remains on the bottom surface of the conductive layer 740 after the annealing process.

Referring to FIG. 7E, the opening S3 penetrating through the dielectric layer 763 exposes the via plug 742 of the conductive layer 740. After forming the dielectric layer 763, referring to FIG. 7F, another seed layer 731 is formed on the dielectric layer 763 around the opening S3 and covering the exposed surface of the via plug 742, and later, another diffusion layer 732 is formed conformally over the opening S3 and covering the seed layer 731. In some embodiments, the diffusion layer 732 covers the seed layer 731 on the dielectric layer 763 around the opening S3, the sidewalls of the opening S3 and the seed layer 731 on the via plug 742. In some embodiments, another conductive layer 730 including metallization patterns is formed on the diffusion layer 732 on the dielectric layer 763 and filled in the opening(s) S3. The conductive layer 730 includes via plug(s) 734 filled in the opening S3 and landed on the via plug 742. Referring to FIG. 7F, the via plug 734 that is disposed directly on the diffusion layer 732 on the seed layer 731 extends through the dielectric layer 763 to physically and electrically connected to the underlying via plug 742. The seed layer 731 and the diffusion layer 732 may be formed using similar materials and methods as the seed layer 750/750′ and the diffusion layer 752, and the details will not be repeated. Also, the conductive layer 730 may be formed using similar materials and methods as the conductive layer 740 but with different metallization patterns, and the description is not repeated herein.

In some embodiments, the material of the conductive layer 730 is different from that of the conductive layer 740, and the materials of the seed layer 731 and the diffusion layer 732 are different from those of the seed layer 750 and the diffusion layer 752.

Referring to FIG. 7F, in some embodiments, following the prior formation of the diffusion layer 732, the conductive layer 730 is formed with dopants 731 embedded therein. In some embodiments, the dopants 731 are or include metal atoms that are initially included within the metal material of the diffusion layer 732, and the dopants 731 may be present in the conductive layer 730 as solitary metal atoms, or in the form as tiny grains or particles. Although not shown in FIG. 7F, the conductive layer 730 may be formed with other metallization patterns such as conductive lines or traces extending along the major surface of the dielectric layer 763.

In some embodiments, by tuning the thicknesses of the diffusion layers 732 relative to the via plug(s) 734, more or less dopants 731 are contained within the via plug(s) 734, when compared with the via plug(s) 742. In some embodiments, a content of the dopants 741 in the conductive layer 740 (via plug 742 and traces 744) is different from a content of the dopants 731 in the conductive layer 730 (via plug 734).

Referring back to FIG. 5 and FIG. 6, following the exemplary process steps and formation methods as illustrated from FIG. 7A to FIG. 7F, within the redistribution structure 160, before forming the conductive layers 162, 164 and 166, the diffusion layers 1622, 1642 and 1662 are formed, and the later formed conductive layers 162, 164 and 166 are formed directly on the diffusion layers 1622, 1642, 1662 and are formed with dopants (e.g. dopants 1623 in the enlarged view of FIG. 5) dispersed therein. Herein, as the dopants may not be visible and will not be shown in certain figures for the simplicity, but it is understood that dopants provided by the diffusion layer(s) are diffused and dispersed into the later formed conductive layer(s), and/or metallic features thereof. Herein, the seed layers or seed patterns are not shown in the figures for simplicity.

In some embodiments, the conductive layer 168 is formed without the diffusion layer there-below and is thus formed without dopants contained therein. Depending on the product designs, one layer or some layers of the conductive layers may be formed without prior formation of the diffusion layer, and the conductive layer may be formed without dopants. Compared with the conductive layer formed without containing dopants therein, the conductive layer containing dopants therein may exhibit stronger mechanical strengths (higher hardness, higher toughness and larger modulus). Compared with via plugs in the conductive layer containing no dopants, the metal materials of the via plugs 162V1/V2 and other via plugs in the conductive layers 162, 164, 166 have smaller crystal grain sizes, leading to stronger mechanical strengths. Accordingly, the redistribution structure (especially stacked via plugs therein) formed with the conductive layer containing dopants is more reliable and endurable through vigorous processing conditions, and the production yield is accordingly enhanced.

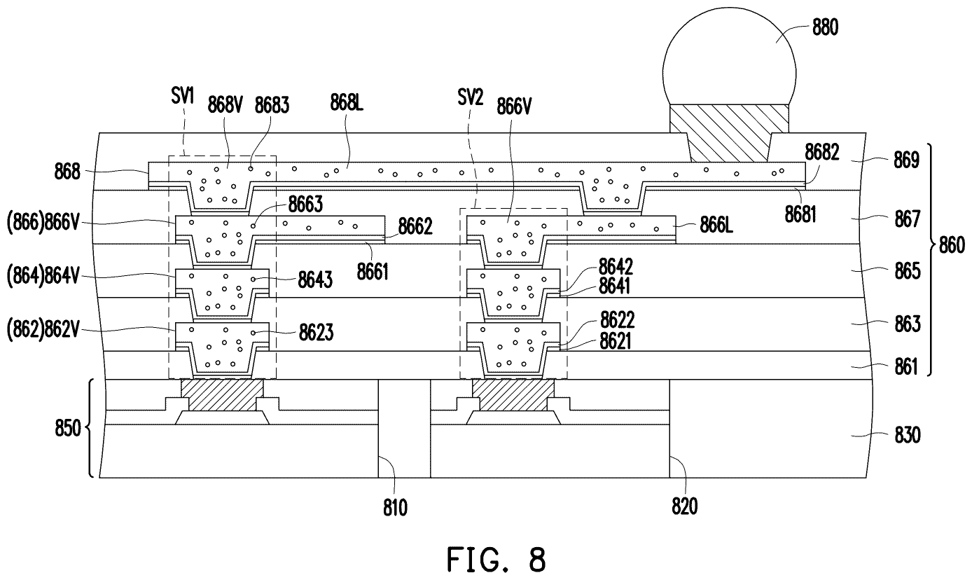

FIG. 8 is a schematic cross-sectional view of a portion of a semiconductor package structure with stacked vias according to an exemplary embodiment of the present disclosure. Following the exemplary process steps and formation methods as illustrated from FIG. 7A to FIG. 7F, the redistribution structure will be formed. Referring to FIG. FIG. 8, the redistribution structure 860 is shown as an example having four layers of metallization patterns 862, 864, 866, 868 (four conductive layers) sandwiched between five dielectric layers 861, 863, 865, 867, 869. In some embodiments, the redistribution structure 860 is formed over the molded structure 850 having semiconductor dies 810 and 820 laterally encapsulated by the insulating molding compound 830. In one embodiment, the material of the molding compound 830 includes epoxy resins, phenolic resins or silicon-containing resins and filler particles such as silica particles.

The metallization patterns 862, 864, 866, 868 may be formed using similar materials and methods for forming the conductive layers 730, 740 with metallization patterns as described in the previous paragraphs and the description is not repeated herein. In some embodiments, the materials of the dielectric layers 861, 863, 865, 867, 869 include polymeric materials such as photo-sensitive polymeric material that is directly patternable using a lithography mask. The dielectric layers 861, 863, 865, 867, 869 may be formed using the same or similar materials and formation methods of the dielectric layers 761, 763 as described in the previous paragraphs. Similarly, the formation of the dielectric layers 861, 863, 865, 867, 869 may involve performing one or more annealing processes, and the annealing process may be performed under the temperature at about 230 degrees Celsius for a period of about 2-6 hours.

Referring to FIG. 8, among the stacking structure of the metallization patterns 862, 864, 866, 868, the stacked structure SV1 (stacked vias) of the via plugs 862V, 864V, 866V and 868V are electrically connected with the below semiconductor die 810, while the stacked structure SV2 (stacked vias) of the via plugs 862V, 864V and 866V are electrically connected with the below semiconductor die 820. In some embodiments, the semiconductor die 810 is electrically connected with the bump connectors 880 (only one is shown) through the stacked structure SV1 and the routing traces 868L of the metallization pattern 868, while the semiconductor die 820 is electrically connected with the bump connector(s) 880 through the routing traces 866L, 868L, the via plug 868V and the stacked structure SV2. In some embodiments, the bump connectors 880 include C4 bumps. Referring further to FIG. 8, in some embodiments, the via plugs 862V, 864V, 866V and 868V have sloped sidewalls. In some embodiments, at least one via plug 868V is laterally shifted with respect to the stacked structure SV2 (stacked vias) of the via plugs 862V, 864V and 868V. In the embodiments, the via plugs 862V, 864V, 866V and 868V in the stacked structure SV1 or SV2 are vertically stacked upon one another.

As seen in FIG. 8, the metallization patterns 862, 864, 866, 868 are formed with diffusion layers 8622, 8642, 8662, 8682 respectively covering their bottom surfaces and sandwiched between their bottom surfaces and the underlying seed layers 8621, 8641, 8661, 8681. The seed layers 8621, 8641, 8661, 8681 and the diffusion layer 8622, 8642, 8662, 8682 may be formed using similar materials and methods as the seed layer 731, 750 and the diffusion layer 732, 752. Similarly, the metallization patterns 862, 864, 866, 868 are formed with dopants 8623, 8643, 8663, 8683 dispersed therein. Through the same or similar formation processes, with the presence of the diffusion layers 8622, 8642, 8662, 8682 resting right below and with the dopants 8623, 8643, 8663, 8683 dispersed therein, the metal materials of the metallization patterns 862, 864, 866, 868 are formed in the preferred crystal orientation, leading to further reduced crystal grain sizes and increased crystal grain boundaries formed therein. Compared with via plugs contains no dopants, the crystal grain sizes of the metal material of the via plugs 862V, 864V, 866V, 868V are smaller, leading to stronger mechanical strengths. Hence, the formed metallization patterns 862, 864, 866, 868, especially the via plugs 862V, 864V, 866V, 868V, are formed with higher mechanical strengths and higher Young's modulus and with minimal or no voids therein. As a result, reliable stacking structure, especially the stacked vias or stacked via plugs, of the redistribution structure can be formed with minimal or no cracking, even undergoing multiple thermal cycles.

By forming the metallization patterns 862, 864, 866, 868 with the dopants 8623, 8643, 8663, 8683, stronger and harder via plugs 862V, 864V, 866V, 868V are formed, and either stacking and staggering the via plugs in the redistribution structure 860 as described above, the redistribution structure 860 is more robust. Accordingly, the redistribution structure becomes more reliable and durable as less defects generate due to the strain in the redistribution structure 860, which improves the process window and design flexibility for the redistribution structure. Hence, for a package or a semiconductor device comprising such redistribution structure, better routing efficiency and the reliability of the redistribution structure are achieved.

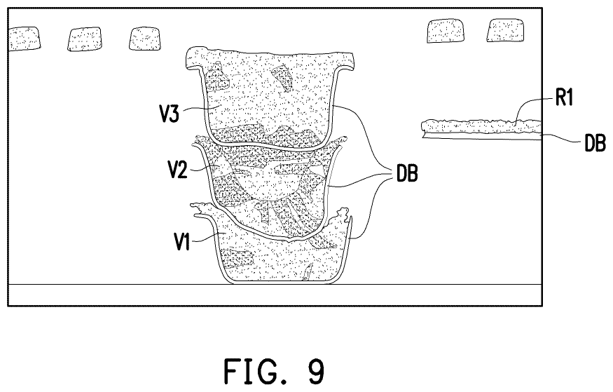

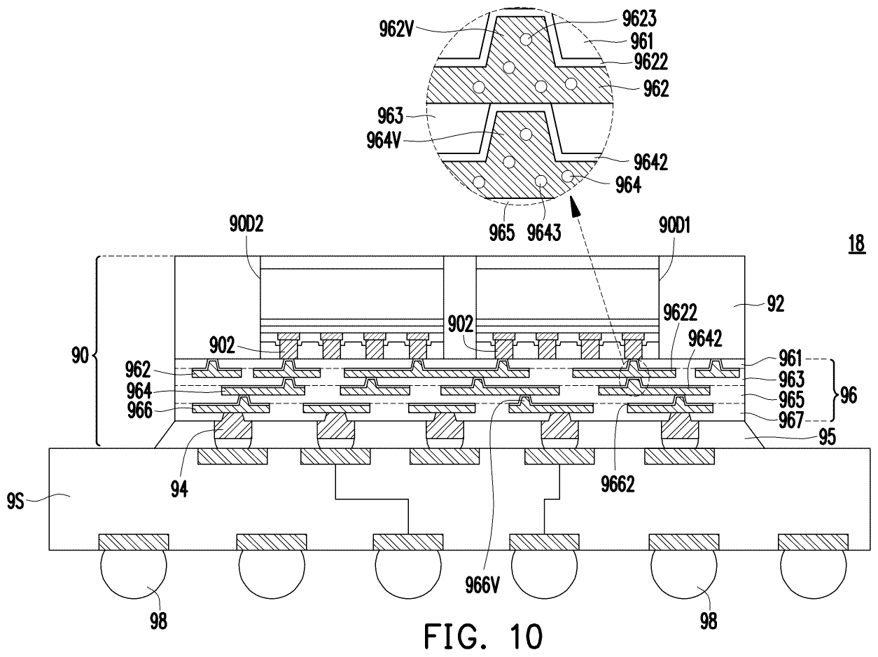

FIG. 9 schematically illustrates the stacked vias and a portion of routing patterns in the redistribution structure in accordance with embodiments of the present disclosure. Referring to FIG. 9, it is seen that via plugs V1, V2 and V3 stacked upon one another are formed with diffusion layers DB respectively covering the bottom surfaces of the via plugs V1, V2 and V3 without covering the top surfaces of the via plugs V1, V2 and V3. As seen in FIG. 9, the diffusion layer DB is located between and sandwiched between the via plugs V1 and V2, and between the via plugs V2 and V3. That is, the diffusion layer DB located between the via plugs V1 and V2 physically separates the via plug V1 from the via plug V2, and the diffusion layer DB located between the via plugs V2 and V3 physically separates the via plug V2 from the via plug V3. Also, the routing trace R1 is formed with the diffusion booting layer DB located on its bottom surface. In some embodiments, the stacked via plugs V1, V2 and V3 are electrically connected with one another.

When compared with a via plug formed by plating without the diffusion layer or dopants therein, for a copper via plug formed with a silver layer thereon (as diffusion layer on its bottom surface), when the thickness of the diffusion layer is about 15% of the bulk thickness of the via plug, and the content of the dopants (e.g., Ag/Ag atoms) in the via plug is about 7 at % (atomic percent), the crystal grain size of copper is reduced by about 30%, the hardness of the via plug is increased by 20% (1.2 times harder), the toughness is increased by about 32% and the modulus (Young's modulus) is increased by about 8% to 10%, if measured using indentation tests.

FIG. 10 is a schematic cross-sectional view illustrating a package structure having stacked vias with the according to some exemplary embodiments of the present disclosure.

Referring to FIG. 10, in some embodiments, a package structure 18 including at least one package unit 90 mounted and bonded to a circuit substrate 9S through the bump connectors 94 is illustrated. In some embodiments, the package unit 90 includes a first semiconductor die 90D1 and a second semiconductor die 90D2 laterally wrapped by an insulating encapsulant 92, a redistribution structure 96 formed on the first semiconductor die 90D1 and the second semiconductor die 90D2 and extending on the encapsulant 92, and the bump connectors 94 located on the redistribution structure 96. In some embodiments, the first semiconductor die 90D1 and the second semiconductor die 90D2 are different types of dies or perform different functions. In some embodiments, the first semiconductor die 90D1 may include one or more of an application-specific integrated circuit (ASIC) chip, an analog chip, a sensor chip, a wireless application chip (such as a Bluetooth chip or a radio frequency chip), a voltage regulator chip or a system-on-a chip (SoC). In some embodiments, the second semiconductor die 90D2 includes one or more memory chips, such as high bandwidth memory (HBM) chips, dynamic random access memory (DRAM) chips or static random access memory (SRAM) chips. In FIG. 10, two dies are shown as the exemplary dies of the package structure, but it is understood that multiple dies or two or more types of dies or different types of dies may be included within the package structure. In certain embodiments, dies and chips may be used interchangeably.

In some embodiments, the first semiconductor die 90D1 and the second semiconductor die 90D2 (facing down, with active surfaces facing the redistribution structure 96) are bonded to the redistribution structure 96 through die connectors 902 of the first and second semiconductor dies 90D1, 90D2. Also, an underfill 95 is filled between the first semiconductor die 90D1 and the second semiconductor die 90D2 and the redistribution structure 96 and surrounding the bump connectors 94. In some embodiments, the underfill 95 fills up the gaps between the package unit 90 and the circuit substrate 9S, and the underfill 95 may overflows to partially cover the sidewalls of the redistribution structure 96. In some embodiments, the first semiconductor die 90D1 and the second semiconductor die 90D2, the redistribution structure 96 are substantially the same or similar to the corresponding elements as described in the above paragraphs, and detailed descriptions will be skipped. As seen in FIG. 10, the circuit substrate 9S may provide dual-side electrical connection and provide further electrical connection through the conductive balls 98. In some embodiments, the circuit substrate 9S is a print circuit board (PCB), a flexible PCB or any suitable laminated circuit substrate. In some embodiments, using round shaped bumps as examples, the size (diameter) of the conductive balls 98 is larger than the size (diameter) of the bump connectors 94. Through these conductive connections and the redistribution structure, the semiconductor dies 90D1, 90D2 of finer pitches are electrically connected with the circuit substrate 9S of further larger pitches.

Following the exemplary process steps and formation methods as illustrated from FIG. 7A to FIG. 7F, the redistribution structure 96 is formed with three conductive layers 962, 964, 966 (as three layers of metallization patterns) sandwiched between four dielectric layers 961, 963, 965, 967. Through the same or similar formation processes, the conductive layers 962, 964, 966 are formed with the diffusion layers 9622, 9642, 9662 right below and with the dopants therein. Herein, the seed layers or seed patterns are not shown in the figures for simplicity. As seen in the partially enlarged view of FIG. 10, the conductive layers 962, 964 are formed with dopants 9623, 9643 therein and with the diffusion layers 9622, 9642 covering the surfaces (top surface in FIG. 10) of the conductive layers 962, 964. Although not shown in FIG. 10, the conductive layer 966 is formed with dopants (metal atoms) therein. In some embodiments, the metallization patterns of the conductive layers 962, 964, 966 include at least via plugs 962V, 964V, 966V. Hence, by forming the conductive layer (with the metal material) containing the dopants, the metallization patterns including the via plugs 962V, 964V, 966V are formed with higher mechanical strengths and higher Young's modulus. As a result, the package structure formed with such redistribution becomes more reliable and provides excellent electrical performance. For the package having such redistribution structure, minimal or no cracking is formed in redistribution structure, especially the stacked vias or stacked via plugs of the redistribution structure, so that reliable and satisfactory electrical interconnection and routing can be achieved.

According to the above exemplary embodiment, the package structure(s) may be suitably formed following the processes for fabricating the integrated fan-out (InFO) wafer-level package structure. More than one or multiple redistribution layers (RDLs) may be provided in the package structure or arranged on both front side and back side of the die(s) or chip(s) for signal redistributions among multiple dies or chips. The structures and/or the processes of the present disclosure are not limited by the exemplary embodiments. According to the above exemplary embodiments, the layout and configuration of the redistribution structure may be suitably formed within the wafer-level package structures. Additionally, the package structure may further include additional dies or sub-package units disposed over or below the dies and another redistribution structures or layers may be formed to electrically connect the additional dies or sub-package units. The structures and/or the processes of the present disclosure are not limited by the exemplary embodiments.

Due to the existence of the dopants within the conductive metallization patterns of the redistribution structure, the redistribution structure exhibits stronger mechanical strength and reliable electrical connection is offered through such redistribution structure. By forming the diffusion layer(s) before forming the metallic material of the conductive metallization patterns in the redistribution structure, the conductive metallization patterns are formed with dopants therein, which strengthens the mechanical properties and reinforces the structural integrity. Through the formation of such redistribution structure, the stacked structure of via plugs has higher mechanical strengths and minimal cracking, leading to improved reliability for the package structure.

The disclosure is not limited neither by the type nor the number of semiconductor packages connected to the circuit substrate. It will be apparent that different types of semiconductor package units may be used to produce semiconductor device package structures including the circuit substrate disclosed herein, and all these semiconductor devices are intended to fall within the scope of the present description and of the attached claims. For example, Chip-On-Wafer-On-Substrate (CoWoS) structures, three-dimensional integrated circuit (3DIC) structures, Chip-on-Wafer (CoW) packages, Package-on-Package (PoP) structures may all be used as the semiconductor package units, alone or in combination.

According to some embodiments, a package includes a molded structure having a first semiconductor die and a second semiconductor die laterally wrapping around by an insulating encapsulant, and a redistribution structure disposed over the molded structure and electrically connected with the first and second semiconductor dies. The redistribution structure comprises a dielectric layer and a stacked via structure embedded in the dielectric layer. The stacked via structure comprises a first via plug, a first diffusion layer including first dopants, a second via plug, and a second diffusion layer including second dopants. The first via plug is disposed on the first diffusion layer. The first via plug includes the first dopants dispersed within a first metal material of the first via plug, and a first surface of the first via plug is covered by the first diffusion layer. The second diffusion layer is disposed over the second via plug. The second via plug disposed on the second diffusion layer includes the second dopants dispersed within a second metal material of the second via plug. The second metal material includes copper.

According to some embodiments, a package structure includes a semiconductor die, an insulating encapsulant laterally wrapping around the semiconductor die, and a redistribution structure disposed on and extending over the semiconductor die and the insulating encapsulant. The redistribution structure is electrically connected with the semiconductor die. The redistribution structure comprises first, second and third dielectric layers, first and second diffusion layers, and first and second conductive via plugs. The first diffusion layer is disposed on the first dielectric layer and covers the first opening of the first dielectric layer. The first diffusion layer includes first dopants. The first dopant comprises silver, zinc or manganese. The first conductive via plug is disposed on the first diffusion layer and fills the first opening with the first diffusion layer sandwiched in-between. The first conductive via plug includes the first dopants dispersed therein. The second dielectric layer is disposed on the first dielectric layer and has a second opening exposing the first conductive via plug. The second diffusion layer is disposed on the second dielectric layer and covers the second opening and the exposed first conductive via plug. The second diffusion layer includes second dopants. The second conductive via plug is disposed on the second diffusion layer and fills in the second opening with the second diffusion layer sandwiched between the first and second conductive via plugs. The second conductive via plug includes the second dopants dispersed therein. The third dielectric layer is disposed on the second dielectric layer and partially covering the second conductive via plug.

According to some embodiments, a manufacturing method for a package structure is provided. After providing a semiconductor die, an insulating encapsulant is formed wrapping around the semiconductor die. A redistribution structure is formed over the insulating encapsulant and on the semiconductor die. The formation of the redistribution structure includes forming a first dielectric layer having a first opening extending through the first dielectric layer, and forming a first diffusion layer on the first dielectric layer and covering the first opening. The first diffusion layer includes first dopants. Later, a first conductive via plug is formed on the first diffusion layer over the first dielectric layer, filling in the first opening with the first diffusion layer sandwiched in-between, and the first conductive via plug includes the first dopants dispersed therein. After forming a second dielectric layer on the first dielectric layer and having a second opening exposing the first conductive via plug, a second diffusion layer is formed on the second dielectric layer and covering the second opening and the exposed first conductive via plug. The second diffusion layer includes second dopants. A second conductive via plug is formed on the second diffusion layer over the second dielectric layer, filling in the second opening with the second diffusion layer between the first and second conductive via plugs. The second conductive via plug includes the second dopants dispersed therein. Then a third dielectric layer is formed on the second dielectric layer and partially covering the second conductive via plug.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package, comprising:
a molded structure comprising a first semiconductor die and a second semiconductor die laterally wrapping around by an insulating encapsulant; and
a redistribution structure, disposed on the molded structure and electrically connected to the first semiconductor die and the second semiconductor die, wherein the redistribution structure comprises a dielectric layer and a stacked via structure in the dielectric layer, wherein the stacked via structure comprises:
a first diffusion layer, including first dopants, wherein the first dopant comprises silver, zinc or manganese;
a first via plug disposed on the first diffusion layer, wherein the first via plug includes a first metal material and the first dopants dispersed within the first metal material;
a second diffusion layer disposed over the first via plug, wherein the second diffusion layer includes second dopants; and
a second via plug disposed on the second diffusion layer, wherein the second via plug includes a second metal material and the second dopants dispersed within the second metal material, and the second metal material comprises copper.

2. The package of claim 1, wherein copper in the second metal material has a preferred crystal orientation of Cu (111).

3. The package of claim 1, wherein the redistribution structure includes first routing traces embedded in the dielectric layer, the first routing traces are connected to the first via plug, and the first routing traces are lined by the first diffusion layer covering surfaces of the first routing traces.

4. The package of claim 3, wherein the redistribution structure includes second routing traces embedded in the dielectric layer, the second routing traces are connected to the second via plug, and the second routing traces are lined by the second diffusion layer covering surfaces of the second routing traces.

5. The package of claim 4, wherein the first routing traces include the first dopants therein, and the second routing traces include the second dopants therein.

6. The package as claimed in claim 1, wherein the first metal material includes copper, and a content of the first dopants in the first via plug is about or less than 12 at % and larger than 5 at %.

7. The package as claimed in claim 6, wherein the second dopants include silver, zinc or manganese, and a content of the second dopants in the second via plug is about or less than 12 at % and larger than 5 at %.

8. A package, comprising:
a semiconductor die; and
an insulating encapsulant laterally wrapping around the semiconductor die; and
a redistribution structure, disposed over the semiconductor die and the insulating encapsulant, and electrically connected with the semiconductor die, wherein the redistribution structure comprises:
a first dielectric layer having a first opening extending through the first dielectric layer;
a first diffusion layer, disposed on the first dielectric layer and covering the first opening, wherein the first diffusion layer includes first dopants;
a first conductive via plug, disposed on the first diffusion layer, wherein the first conductive via plug includes the first dopants dispersed therein;
a second dielectric layer, disposed on the first dielectric layer and having a second opening exposing the first conductive via plug;
a second diffusion layer, disposed over the second dielectric layer and covering the second opening, wherein the second diffusion layer includes second dopants;
a second conductive via plug, disposed on the second diffusion layer, wherein the second conductive via plug includes the second dopants dispersed therein; and
a third dielectric layer, disposed on the second dielectric layer and partially covering the second conductive via plug.

9. The package as claimed in claim 8, wherein a material of the first diffusion layer includes silver, zinc or manganese, and a material of the second diffusion layer includes silver, zinc or manganese.

10. The package as claimed in claim 8, wherein the first conductive via plug includes copper, the first dopants include silver, and a content of the first dopants in the first conductive via plug is about or less than 12 at % and larger than 5 at %.

11. The package as claimed in claim 8, wherein the second conductive via plug includes copper, the second dopants include silver, and a content of the second dopants in the second conductive via plug is about or less than 12 at % and larger than 5 at %.

12. The package as claimed in claim 8, wherein a content of the first dopants in the first conductive via plug is different from a content of the second dopants in the second conductive via plug.

13. The package as claimed in claim 8, further comprising a third conductive via plug disposed on the third dielectric layer and disposed directly on the second conductive via plug, wherein the third conductive via plug contains no dopants therein.

14. The package as claimed in claim 13, wherein the first conductive via plug is made of a first metal material of a first crystal grain size, the second conductive via plug is made of a second metal material of a second crystal grain size, the third conductive via plug is made of a third metal material of a third crystal grain size, and the first crystal grain size is about the same as the second crystal grain size and smaller than the third crystal grain size.

15. The package as claimed in claim 8, further comprising a circuit substrate and connectors disposed on the redistribution structure, wherein the circuit substrate is electrically connected with the redistribution structure and the semiconductor die through the connectors.

16. A method for forming a package, comprising:
providing a semiconductor die;
forming an insulating encapsulant wrapping around the semiconductor die; and
forming a redistribution structure over the insulating encapsulant and on the semiconductor die, wherein forming the redistribution structure includes:
forming a first dielectric layer having a first opening extending through the first dielectric layer;
forming a first diffusion layer on the first dielectric layer and covering the first opening, wherein the first diffusion layer includes first dopants;
forming a first conductive via plug on the first diffusion layer over the first dielectric layer, wherein the first conductive via plug is filled in the first opening with the first diffusion layer sandwiched in-between, and the first conductive via plug includes the first dopants dispersed therein;
forming a second dielectric layer on the first dielectric layer and having a second opening exposing the first conductive via plug;
forming a second diffusion layer on the second dielectric layer and covering the second opening and the exposed first conductive via plug, wherein the second diffusion layer includes second dopants;
forming a second conductive via plug on the second diffusion layer over the second dielectric layer, wherein the second conductive via plug is filled in the second opening with the second diffusion layer between the first and second conductive via plugs, and the second conductive via plug includes the second dopants dispersed therein; and
forming a third dielectric layer on the second dielectric layer and partially covering the second conductive via plug.

17. The method of claim 16, wherein forming a first diffusion layer includes performing an electrochemical plating process to form a silver layer, and the first dopants include silver.

18. The method of claim 17, wherein forming a first conductive via plug includes performing copper electrochemical plating to incorporate silver as the first dopants in the first conductive via plug.

19. The method of claim 16, wherein forming a second diffusion layer includes performing an electrochemical plating process to form a silver layer, and the second dopants include silver.

20. The method of claim 19, wherein forming a second conductive via plug includes performing copper electrochemical plating to incorporate silver as the second dopants in the second conductive via plug.
